(19) United States
(12) Patent Application Publication
(10) Pub. No.: US 2017/0133204 A1
(43) Pub. Date: May 11, 2017

(54) Member for Plasma Processing Apparatus and Plasma Processing Apparatus

(71) Applicant: TOKYO ELECTRON LIMITED, Tokyo (JP)

(72) Inventors: Kazuki MOYAMA, Miyagi (JP); Toyohiro KAMADA, Nirasaki City (JP); Hiroyuki IKUTA, Nirasaki City (JP); Yuya MINOURA, Nirasaki City (JP)

(21) Appl. No.: 15/345,106

(22) Filed: Nov. 7, 2016

(30) Foreign Application Priority Data
Nov. 9, 2015 (JP) 2015-219797

(51) Int. Cl. H01J 37/32; C23C 16/50

(52) U.S. Cl. CPC H01J 37/32192; C23C 16/50; H01J 2237/334; H01J 2237/3321

(57) ABSTRACT

There is provided a member for a plasma processing apparatus, the member constituting the plasma processing apparatus configured to generate plasma in a processing space of a processing container and to perform plasma processing on an object to be processed. The member includes a face of the member exposed to the plasma and coated with a protection film. The protection film includes a columnar structure having a plurality of column-shaped portions in substantially cylindrical shapes extending in a thickness direction of the film. The plurality of column-shaped portions is adjacent to one another without gaps therebetween.

### CROSS-REFERENCE TO RELATED APPLICATION

This application claims the benefit of Japanese Patent Application No. 2015-219797, filed on Nov. 9, 2015, in the Japan Patent Office, the disclosure of which is incorporated herein in its entirety by reference.

### TECHNICAL FIELD

The present disclosure relates to a member for a plasma processing apparatus, wherein the member constitutes a plasma processing apparatus for performing plasma processing on an object to be processed and has a protection film coated on a face thereof exposed to plasma, and further relates to a plasma processing apparatus including the member for the plasma processing apparatus.

### BACKGROUND

As a conventional plasma processing apparatus for performing predetermined plasma processing on an object to be processed, e.g., a semiconductor wafer, a plasma processing apparatus employing a radial line slot antenna has been known. In the radial line slot antenna, a slot plate having a wave retardation plate placed thereon and a plurality of slots is disposed above a dielectric window disposed at an opening of a ceiling face of a processing container, and a coaxial wave guide is connected to a central portion of the slot plate. With this configuration, a microwave generated by a microwave generator passes through the coaxial wave guide and is radially transmitted from the wave retardation plate in a diametric direction to generate a circularly polarized wave in the slot plate, which in turn is radiated from the slot plate via the dielectric window into the processing container. High-density plasma having a low electron temperature can be generated by this microwave under a low pressure in the processing chamber, and plasma processing, for example, film deposition processing, etching processing, etc., is performed by the generated plasma.

In such plasma processing apparatus, there was a problem in that since an electron temperature increases, for example, around the dielectric window or a metal member for supporting the dielectric window, the metal member is abraded by a sputter action of the plasma in a state where the metal member is exposed to a plasma generating space, resulting in metal contamination in a processing space. As for a specific metal member, for example, aluminum (Al) or aluminum alloy is used, causing a problem of aluminum contamination due to aluminum particles.

Accordingly, in order to reduce the metal contamination caused by the metal member in the processing container of the plasma processing apparatus, a technique of coating the metal member with a thermally resistant insulator, for example, Y₂O₃, or the like has been known. Furthermore, in order to minimize contamination of the member caused by metal or particles of a substrate, a technique of forming an yttria containing film (coating) on various components including a ceramic member in a semiconductor material processing apparatus has been known.

Recently, however, according to demand for high density integration and high speed of a semiconductor integrated circuit, a requirement for various contamination preventing measures in the processing container in which processing of a semiconductor wafer is performed becomes more stringent. In this regard, a problem has been found in that an action of the plasma produces yttria particles from the yttria containing film coated on a member such as a dielectric, etc. constituting the processing container.

The aforementioned conventional techniques make an issue of the particles produced from the substrate or metal, but hardly mention particles produced from the film coated on various kinds of members or an inner wall of the processing container.

### SUMMARY

Some embodiments of the present disclosure provide a technique enabling reduction of particles produced from a protection film of a member for a plasma processing apparatus, as compared with a related art, wherein the protection film is coated on a face of the member exposed to plasma.

According to one embodiment of the present disclosure, there is provided a member for a plasma processing apparatus configured to generate plasma in a processing space of a processing container and to perform plasma processing on an object to be processed, the member including a face of the member exposed to the plasma and coated with a protection film. The protection film includes a columnar structure having a plurality of column-shaped portions in substantially cylindrical shapes extending in a thickness direction of the film, the plurality of column-shaped portions being collected to be adjacent to one another without gaps therebetween.

According to another embodiment of the present disclosure, there is provided a plasma processing apparatus configured to generate plasma in a processing space of a processing container and to perform plasma processing on an object to be processed, wherein the plasma processing apparatus includes a member for the plasma processing apparatus, the member having a protection film coated on a face of the member exposed to the plasma, and the protection film includes a columnar structure having a plurality of column-shaped portions in substantially cylindrical shapes extending in a thickness direction of the film, the plurality of column-shaped portions being collected to be adjacent to one another without gaps therebetween.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view schematically showing a configuration of a plasma processing apparatus according to an embodiment of the present disclosure.

FIG. 2 is a schematic view of a surface structure of a protection film.

FIG. 3 is a schematic view of a section structure of the protection film.

FIG. 4 is a graph showing a film deposition rate when film deposition processing is performed using a microwave-transmissive plate protected by a protection film having no columnar structure, illustrating changes in the film deposition rate over time.

FIG. 5 is a graph showing a film deposition rate when film deposition processing is performed using a microwave-transmissive plate protected by a protection film having a columnar structure, illustrating changes in the film deposition rate over time.

FIG. 6 is a graph showing a correlation between a surface roughness of a substrate and a roughness of a coating film.

FIG. 7 is a graph showing average values of yttrium contamination generated on a wafer due to plasma processing within a measurement time.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Furthermore, in the specification and drawings, components having substantially identical functional configurations are designated by the same reference numeral and thus repeated descriptions thereof will be omitted.

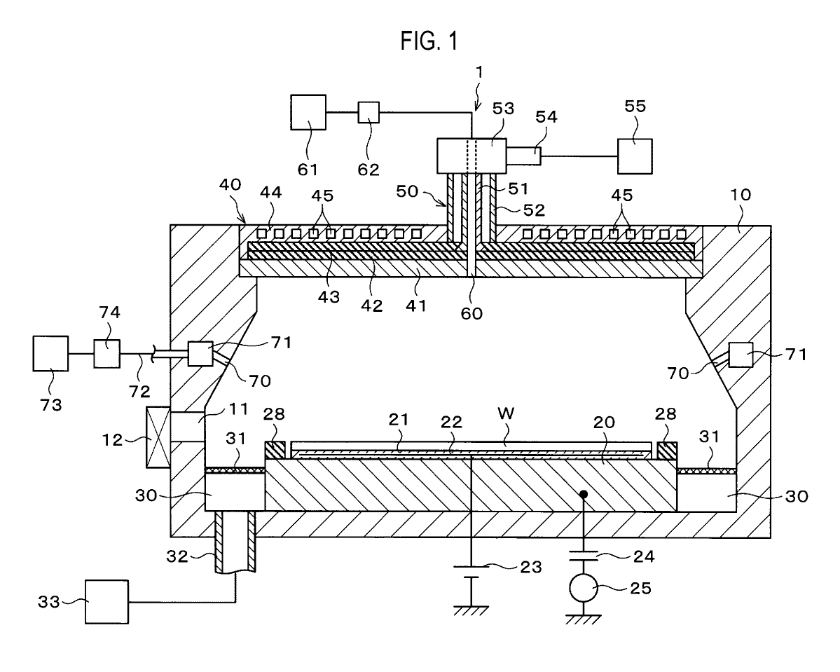

FIG. 1 is a longitudinal sectional view schematically showing a configuration of plasma processing apparatus 1 according to an embodiment of the present disclosure. In this embodiment, the plasma processing apparatus 1 will be described by way of example in connection with a film deposition apparatus for performing plasma chemical vapor deposition (CVD) processing on a surface (top surface) of a wafer W as an object to be processed. Moreover, the present disclosure is applicable to a general apparatus for performing plasma processing on an object to be processed using plasma, and is not limited to embodiments to be described below.

The plasma processing apparatus 1 has a processing container 10 as shown in FIG. 1. The processing container 10 has a substantially cylindrical shape with an open ceiling face, and a radial line slot antenna 40 to be described later is disposed in the open ceiling face. Further, a carrying-in/out opening 11 for an object to be processed is formed in a side surface of the processing container 10, and a gate valve 12 is provided to the carrying-in/out opening 11. The processing container 10 is configured to hermetically seal an interior thereof. Furthermore, the processing container 10 is made of metal such as aluminum, stainless steel, or the like, and the processing container 10 is electrically grounded.

A cylindrical loading board 20 having a top surface on which a wafer W is to be loaded is installed on a floor in the processing container 10. The loading board 20 is made of, for example, aluminum nitride (AlN), etc.

An electrostatic chuck 21 is installed on the top surface of the loading board 20. The electrostatic chuck 21 has a configuration in which an electrode 22 is interposed between insulating materials. The electrode 22 is connected to a direct current power source 23 provided outside the processing container 10. A Coulomb force is generated in a surface of the loading board 20 by the direct current power source 23 to enable the wafer W to be electrostatically sucked on the loading board 20.

In addition, a high frequency power source 25 for a RF bias may be connected to the loading board 20 via a condenser 24. The high frequency power source 25 outputs a constant frequency, for example, a high frequency of 13.56 MHz, which is suitable for control of ion energy incident on the wafer W, with predetermined power.

An annular focus ring 28 is installed on the top surface of the loading board 20 to surround the wafer W placed on the electrostatic chuck 21. The focus ring 28 is made of an insulative material such as ceramics, quartz, etc., and the focus ring 28 functions to enhance uniformity of the plasma processing.

One or more elevation pins (not shown) are installed below the loading board 20 to support the wafer W from below and to lift or lower the wafer. The elevation pins are configured to penetrate a through hole (not shown) formed in the loading board 20 so as to protrude from the top surface of the loading board 20.

An annular evacuation space 30 is formed around the loading board 20 and between the loading board 20 and the side surface of the processing container 10. An annular baffle plate 31 with a plurality of evacuation holes formed therein is provided at an upper portion of the evacuation space 30 to uniformly evacuate the interior of the processing container 10. An evacuation duct 32 is connected to a lower portion of the evacuation space 30, which is a bottom surface of the processing container 10. Any number of evacuation ducts 32 may be set and a plurality of evacuation ducts may be formed in a circumferential direction. For example, the evacuation duct 32 is connected to an evacuation device 33 having a vacuum pump. The evacuation device 33 can depressurize an atmosphere in the processing container 10 to a predetermined degree of vacuum.

The radial line slot antenna 40 functioning as a ceiling plate, which supplies microwaves for generating the plasma, is installed in the opening of the ceiling face of the processing container 10. The radial line slot antenna 40 has a microwave-transmissive plate 41, a slot plate 42, a wave retardation plate 43 and a shield cover 44.

The microwave-transmissive plate 41 is hermetically installed in the opening of the ceiling face of the processing container 10 via a sealing material (not shown), e.g., O-ring, etc. therebetween. Accordingly, the interior of the processing container 10 is hermetically maintained. A dielectric, e.g., quartz, Al₂O₃, AlN or the like, is used for the microwave-transmissive plate 41, and the microwave-transmissive plate 41 allows the microwave to be transmitted therethrough.

The slot plate 42 is installed on a top surface of the microwave-transmissive plate 41 such that the slot plate is located opposite the loading board 20. A plurality of slots is formed in the slot plate 42, which functions as an antenna. A conductive material, e.g., cooper, aluminum, nickel or the like, is used for the slot plate 42.

The wave retardation plate 43 is installed on a top surface of the slot plate 42. A low-loss dielectric, e.g., quartz, Al₂O₃, AlN or the like, is used for the wave retardation plate 43, and the wave retardation plate 43 shortens the wavelength of the microwave.

The shield cover 44 is installed on a top surface of the wave retardation plate 43 to cover the wave retardation plate 43 and the slot plate 42. For example, a plurality of circular ring-shaped flow passages 45 for allowing a cooling medium to flow therein are formed in the shield cover 44. With the cooling medium flowing in the flow passages 45, the microwave-transmissive plate 41, the slot plate 42, the wave retardation plate 43 and the shield cover 44 are adjusted to have predetermined temperatures.

A coaxial wave guide 50 is connected to a central portion of the shield cover 44. The coaxial wave guide 50 has an inner conductor 51 and an outer duct 52. The inner conductor 51 is connected to the slot plate 42. A portion of the inner conductor 51, which is adjacent to the slot plate 42, has a conical shape to allow the microwave to effectively propagate to the slot plate 42.

A mode converter 53 for converting the microwave to a predetermined vibration mode, a rectangular wave guide 54, and a microwave generator 55 for generating microwaves are connected to the coaxial wave guide 50 in this order from the coaxial wave guide 50. The microwave generator 55 generates microwaves with a predetermined frequency, for example, 2.45 GHz.

With this configuration, the microwave generated by the microwave generator 55 sequentially propagates through the rectangular wave guide 54, the mode converter 53 and the coaxial wave guide 50, and is then supplied into the radial line slot antenna 40 so that the microwave is compressed to be a short wavelength in the wave retardation plate 43 and the slot plate 42 generates a circularly polarized wave which in turn is transmitted from the slot plate 42 through the microwave-transmissive plate 41 and radiated into the processing container 10. This microwave can cause process gases to be plasma states in the processing container 10, and the plasma can perform plasma processing on the wafer W.

A first process gas supplying duct 60 serving as a first process gas supplying part is installed at the ceiling face of the processing container 10, i.e., at a central portion of the radial line slot antenna 40. The first process gas supplying duct 60 penetrates through the radial line slot antenna 40 so that one end of the first process gas supplying duct 60 is open below the microwave-transmissive plate 41. In addition, the first process gas supplying duct 60 penetrates through the interior of the inner conductor 51 of the coaxial wave guide 50 and also through the mode converter 53, so that the other end of the first process gas supplying duct 60 is connected to a first process gas supplying source 61. Process gases, for example, TSA (trisilylamine), N₂ gas, H₂ gas, and Ar gas, are separately stored within the first process gas supplying source 61. Among the gases, TSA, N₂ gas and H₂ gas are raw material gases for depositing an SiN film, and Ar gas is a gas for exciting the plasma. Moreover, hereinafter, these process gases may be referred to as first process gases. Further, a group of supplying equipment 62 including a valve or a flow control part for controlling flow of the first process gases, or the like is installed in the first process gas supplying duct 60.

As shown in FIG. 1, a second process gas supplying duct 70 serving as a second process gas supplying part is installed in the side surface of the processing container 10. A plurality of second process gas supplying ducts 70, e.g., 24 second process gas supplying ducts, are installed equidistantly in a circumferential direction in the side surface of the processing container 10. One end of the second process gas supplying duct 70 is open in the side surface of the processing container 10, and the other end thereof is connected to a buffer part 71. The second process gas supplying duct 70 is slantly disposed such that the one end of the second process gas supplying duct is placed below the other end thereof.

The buffer part 71 is annularly arranged within a sidewall of the processing container 10 and is provided in common for the plurality of second process gas supplying ducts 70. A second process gas supplying source 73 is connected to the buffer part 71 via a supplying duct 72. Process gases, for example, TSA (trisilylamine), N₂ gas, H₂ gas and Ar gas, are separately stored in the second process gas supplying source 73. Moreover, hereinafter, these process gases may be referred to as second process gases. Further, a group of supplying equipment 74 including a valve or a flow control part for controlling flow of the second process gases, or the like is installed in the supplying duct 72.

The first process gas from the first process gas supplying duct 60 is supplied toward a central portion of the wafer W, while the second process gas from the second process gas supplying duct 70 is supplied toward an outer peripheral portion of the wafer W.

The first process gas and the second process gas supplied respectively from the first process gas supplying duct 60 and the second process gas supplying duct 70 into the processing container 10 may be the same gas or different kinds of gases and also may be supplied at respective independent flow rates or at any ratio of flow rates.

In the aforementioned plasma processing apparatus 1 that performs plasma CVD processing on a surface of the wafer W as an object to be processed and deposits a film, e.g., SiN film, a metal such as aluminum, stainless steel, or the like is used for the processing container 10 and for example, AlN is used for the loading board 20. Moreover, the dielectric, e.g., quartz, Al₂O₃, AlN, or the like is used for the microwave-transmissive plate 41. As such, a member containing a metal such as aluminum, or the like is used as a member exposed to plasma in a state where the plasma is generated in the processing container 10. It has been found that if the member containing the metal is exposed to the plasma, the metal member is abraded by a sputter action of the plasma, causing metal contamination in a processing space. For example, the space in the processing container 10 becomes contaminated with aluminum particles.

In particular, in the plasma processing apparatus 1 according to this embodiment, the aforementioned problem becomes significant since microwave plasma in which plasma has a high electron temperature is employed and high density plasma is generated around the microwave-transmissive plate 41.

It has been conventionally known that a method of forming a yttria containing film deals with this problem of metal contamination in the processing container 10, and a general plasma processing apparatus dealt with this problem by coating each member with a coating material using a technique such as thermal spraying (for example, atmospheric plasma spraying), etc. As for a conventionally known coating film, a film containing yttrium such as Y₂O₃, YF₃, or the like has been known and is coated on each member with a thickness of 100 μm or more.

The inventors found through various experiments that since the film containing yttrium such as Y₂O₃, YF₃, or the like is exposed to plasma in the plasma processing apparatus, particles containing yttrium are also produced from the film; and that the film is exposed to and abraded by the plasma, thereby changing the surface roughness of the film to affect a processing efficiency in the plasma processing apparatus. The inventors have conducted a study for a technique of reducing such phenomenon as compared with a related art and obtained the following knowledge.

That is to say, the inventors found that when each member dielectric, or the like that is an object to be protected, constitutes the processing container 10, and is exposed to plasma and is coated, the coating film (hereinafter, also referred to as “film” or “protection film”) is formed with a thickness not less than 10 μm but not greater than 100 μm; a surface roughness of a base material (an object to be protected), etc. on which the protection film is to be formed is lowered so that the protection film may have a surface roughness not greater than 3 μm; and particles produced from the protection film can be reduced as compared with a related art by forming the protection film to have a columnar structure. Hereinafter, characteristics of this protection film will be described with reference to graphs as desired.

### (Material Constituting Protection Film)

As for the material constituting the protection film, it is preferable to employ a plasma-resistant material, for example, oxide-based ceramics such as yttria, etc., metal fluoride, metal acid fluoride, and metal carbide.

### (Thickness of Protection Film)

It is preferable that the protection film to be formed has a thickness not less than 10 μm but not greater than 100 μm. This is because if the thickness of the protection film is less than 10 μm, the protection film is abraded by a sputter action, or the like when exposed to the plasma, whereby sufficient protection performance of the protection film cannot be expected.

Meanwhile, if the thickness of the protection film is greater than 100 μm, the thickness of the protection film is excessively large so that breakage or delamination of the protection film may occur. In addition, the costs required for forming the protection film are increased, thereby deteriorating productivity.

### (Columnar Structure of Protection Film)

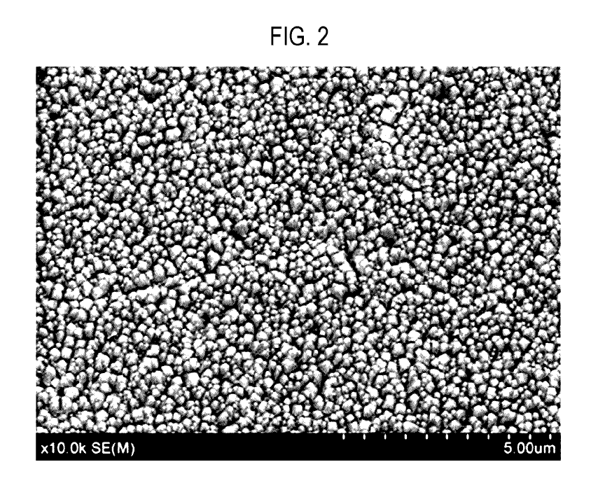

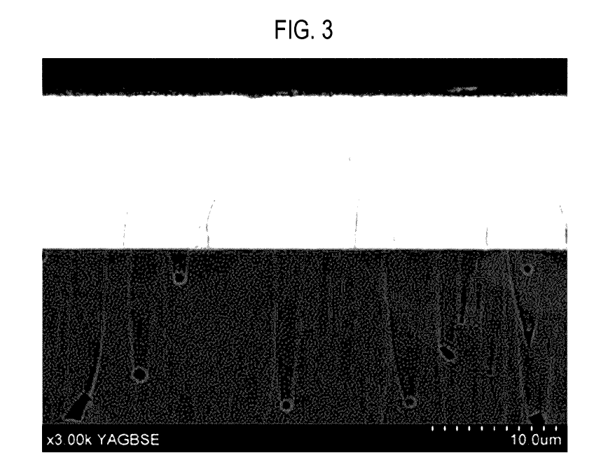

It is preferable that a structure of the protection film to be formed has a columnar shape. As for a specific columnar structure, it is desirable that a width (column diameter) of each column (column-shaped portion) in the columnar structure extending in a thickness direction of the film is less than 0.5 μm in performing SEM observation. FIGS. 2 and 3 are SEM photographs of the protection film according to this embodiment, wherein FIG. 2 is a schematic view of a surface structure of the protection film (×10,000 times), and FIG. 3 is a schematic view of a section structure of the protection film (×3,000 times). Further, a layer disposed at an upper portion in FIG. 3 is a layer of the protection film.

As shown in FIGS. 2 and 3, the protection film according to this embodiment is formed by combining a plurality of column-shaped portions adjacent to one another without any gap, wherein each of the column-shaped portions has a substantially cylindrical shape of a somewhat constant diameter (for example, a diameter less than 0.5 μm). Since this columnar structure is configured such that all of the column-shaped portions extend in a generally identical predetermined direction (in a thickness direction of the film), for example, even in the state where the protection film is exposed to and abraded by the plasma, the surface roughness of the abraded protection film remains substantially unchanged as compared with the surface roughness of the protection film before undergoing the abrasion. Accordingly, it is possible to perform plasma processing without a substantial change between processing efficiency in the plasma processing apparatus at an initial stage in which the protection film has been formed and processing efficiency in the plasma processing apparatus after a predetermined time elapses. Further, various processing such as, e.g., film deposition processing or etching processing, may be considered as the processing performed in the plasma processing apparatus.

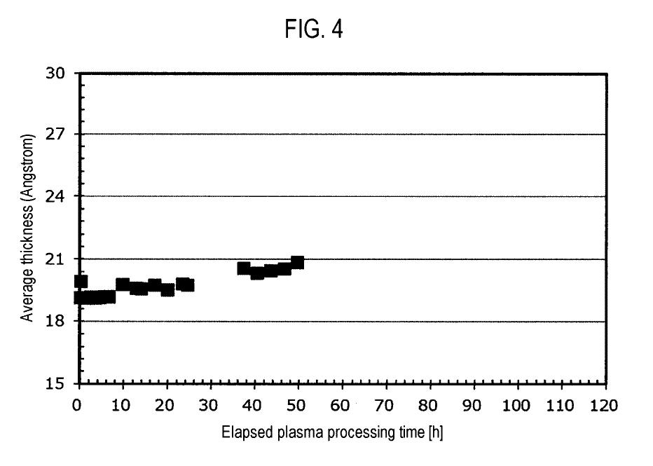

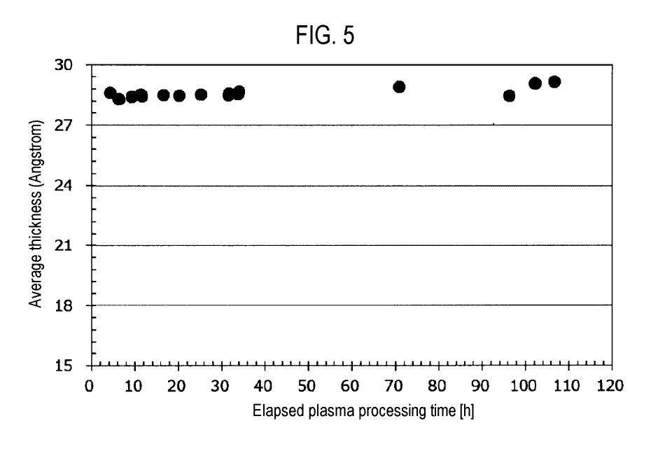

FIG. 4 is a graph showing an average thickness of deposited films per 300 seconds, i.e., a film deposition rate, when film deposition processing is performed in the plasma processing apparatus 1 configured as shown in FIG. 1 by using the microwave-transmissive plate 41 protected by a protection film having no columnar structure, and shows a change in the film deposition rate over time. On the other hand, FIG. 5 is a graph showing an average thickness of deposited films per 300 seconds, i.e., a film deposition rate, when film deposition processing is performed in the plasma processing apparatus 1 configured as shown in FIG. 1 by using the microwave-transmissive plate 41 protected by the protection film having a columnar structure, and shows a change in the film deposition rate over time.

As shown in FIG. 4, when the microwave-transmissive plate 41 protected by the protection film having no columnar structure is employed, the film deposition rate is remarkably changed over time. In particular, the film deposition rate immediately after initiation of film deposition (in the graph, a time point adjacent to an elapsed time of zero (0)) is significantly different from that after a predetermined time elapses. That is to say, it can be seen that even though certain film deposition processing has been performed using the plasma processing apparatus, the film deposition rate varies with time so that stable film deposition processing cannot be realized.

Meanwhile, as shown in FIG. 5, when the microwave-transmissive plate 41 protected by the protection film having a columnar structure is employed, the film deposition rate was not remarkably changed over time. That is to say, it can be seen that if certain film deposition processing is performed using the plasma processing apparatus, the film deposition rate does not vary with time so that stable film deposition processing can be realized.

### (Surface Roughness of Protection Film)

It is preferable that the surface roughness of the protection film to be formed is not greater than 3 μm. The lower the value of the surface roughness of the protection film is, the higher the planarity of the protection film is. Thus, abrasion caused by the sputter action, or the like of the plasma is suppressed when the protection film is exposed to the plasma, thereby realizing stable plasma processing.

Moreover, since the protection film is exposed to and abraded by the plasma, the surface roughness of the protection film varies with time, wherein it is preferable that such time-varying change is small. Since the surface roughness of the protection film does not largely vary with time, particles are not greatly produced and stable processing can be continuously performed even when the plasma processing is performed over a long period of time.

As described above, the protection film according to this embodiment is constructed by the columnar structures with extremely small gaps therebetween, as shown in FIGS. 2 and 3, and is configured such that all of the column-shaped portions extend in a substantially identical predetermined direction (the thickness direction of the film). Since such columnar structure and the surface roughness are closely related to each other and the protection film is configured with the columnar structure, the surface roughness of the protection film is not largely changed and is maintained at a predetermined value (for example, not greater than 3 μm) even when the surface of the protection film is abraded. That is to say, by coating each member of the plasma processing apparatus with the protection film, the stable plasma processing in which the film deposition rate does not vary with time is realized as shown in FIG. 5.

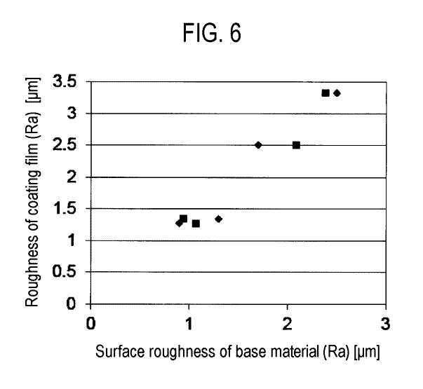

Furthermore, considering a correlation between the surface roughness of the protection film to be formed and the roughness of the base material (the object to be protected), the inventors investigated their correlation. FIG. 6 is a graph showing a correlation between the surface roughness of the base material and the roughness of the coating film (the protection film).

As shown in FIG. 6, since the surface roughness of the base material and the roughness of the coating film are in a correlation in which they are substantially coincident with each other, when the protection film having a surface roughness not greater than 3 μm is formed, it is preferable that the base material (the object to be protected) on which the protection member is to be formed also has the same surface roughness of not greater than 3 μm.

### (Method for Forming Protection Film)

Some embodiments employ, for example, a (high frequency) ion plating method as a method of forming the protection film. The ion plating method is a technique in which a deposition material evaporated by an electron beam is ionized in plasma and a bias is applied to a base material (an object to be protected) for injecting ions into the base material, thereby forming a film (protection film) on the base material.

Since the ion plating method is a well-known method that can be seen with reference to for example, Japanese Patent Laid-Open Publication No. 2000-345319, a detailed description thereof will be omitted herein. However, it is necessary that the protection film according to this embodiment has a thickness of not less than 10 μm but not greater than 100 μm, has a surface roughness of not greater than 3 μm and also has the columnar structure.

By coating each member or dielectric of the plasma processing apparatus with the protection film according to this embodiment described above, it is possible to reduce the amount of particles (for example, particles of yttria) produced from the protection film when each member or dielectric is exposed to plasma, as compared with the related art. In addition, reduction of particles produced from the protection film will be described in an example set forth later.

By forming the protection film to have a thickness of not less than 10 μm but not greater than 100 μm, it is possible to realize sufficient protection performance without generating breakage or delamination of the protection film. In addition, by forming the protection film to have a surface roughness of not greater than 3 μm and to have the columnar structure, even when the protection is exposed to and abraded by the plasma, the surface roughness thereof does not largely vary with time, whereby stable plasma processing can be continuously performed.

Although one example of the embodiment of the present disclosure has been described above, the present disclosure is not limited to the illustrated version. It is apparent to those skilled in the art that various changes and modifications can be conceived within the scope of and spirit stated in the claims and it is understood that the changes and modifications naturally fall within the technical scope of the present disclosure.

### Example

As an example of the present disclosure, identical members (microwave-transmissive plates 41) were coated with a conventional protection film (Comparative Example) formed by means of atmospheric plasma spraying and the protection film (Example) according to the present disclosure formed by the ion plating method, respectively, and were subjected to plasma processing under the same condition, in the plasma processing apparatus having the configuration shown in FIG. 1. In addition, the amounts of particles produced from the protection films over an elapsed time in the plasma processing were measured and average values of the amounts of particles produced from the protection films were calculated. The protection film (Y₂O₃) containing yttrium was employed as the protection film and yttria particles (Y particles) were used as the particles to be measured. The condition of the plasma processing was process gas flow rates of NH₃/H₂/Ar=19/780/770 sccm, a pressure in the processing container of 2 Torr, and a microwave power of 2,500 W (3,600 sec).

A film having a thickness of 15 μm and a surface roughness of 2 μm and configured with the columnar structure was used as the protection film according to the present disclosure (Example). Meanwhile, a film having a thickness of 100 μm and a surface roughness of 6 μm was used as a conventional protection film (Comparative Example).

The amount of yttria particles in the processing container after the plasma processing was conducted for 130 hours in the plasma processing apparatus using the protection film regarding this Example was extremely smaller than the amount of yttria particles in the processing container after the plasma-process was conducted for 130 hours in the plasma processing apparatus using the protection film regarding the Comparative Example. Specifically, it was confirmed that the amount of yttria particles, which was 13 times the amount of yttria particles in the Example, was produced in the Comparative Example.

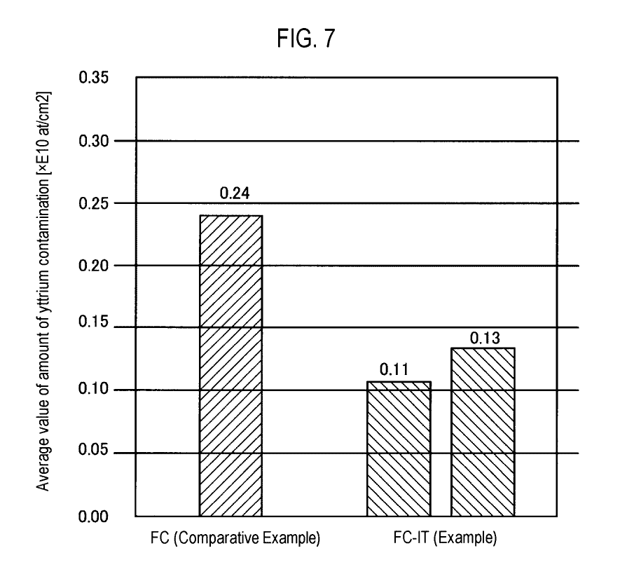

Furthermore, FIG. 7 is a graph showing average values (Y contamination) of the amounts of yttrium contamination generated on the wafers due to the plasma processing for a measurement time of 400 hours in the Example and Comparative Example, respectively. Moreover, the measurement was performed twice for this Example.

As shown in FIG. 7, average values of yttrium contamination generated on the wafers in the Example were 0.13(×E10 at/cm²) and 0.11(×E10 at/cm²). Meanwhile, the average value of yttrium contamination generated on the wafer in the Comparative Example was 0.24(×E10 at/cm²). That is to say, it was found that the yttrium contamination, which was 2 times the yttrium contamination in the Example, was generated in the Comparative Example.

It was found from these results that the amount of yttria particles produced in the processing container using the protection film regarding this Example was reduced as compared with the case where the protection film regarding the Comparative Example was employed, resulting in a reduction in the amount of yttrium contamination generated on the wafer. That is to say, it was demonstrated that by coating the member of the plasma processing apparatus, which is to be exposed to the plasma, with the protection film according to the present disclosure, it is possible to reduce the particles produced from the protection film as compared with a related art.

The present disclosure is applicable to a member for plasma processing apparatus, wherein the member constitutes plasma processing apparatus for performing plasma processing on an object to be processed and has a protection film coated on a face of the member exposed to plasma, and a plasma processing apparatus having the member for the plasma processing apparatus.

According to the present disclosure in some embodiments, it is possible to reduce particles produced from the protection film of the member for the plasma processing apparatus, as compared with a related art, wherein the protection film is coated on a face of the member exposed to plasma.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A member for a plasma processing apparatus, the member constituting the plasma processing apparatus configured to generate plasma in a processing space of a processing container and to perform plasma processing on an object to be processed, the member comprising a face of the member exposed to the plasma and coated with a protection film,
wherein the protection film includes a columnar structure having a plurality of column-shaped portions in substantially cylindrical shapes extending in a thickness direction of the film, the plurality of column-shaped portions being collected to be adjacent to one another without gaps therebetween.

2. The member for the plasma processing apparatus of claim 1, wherein the protection film has a thickness not less than 10 μm but not greater than 100 μm.

3. The member for the plasma processing apparatus of claim 1, wherein the protection film has a surface roughness not greater than 3 μm.

4. The member for the plasma processing apparatus of claim 1, wherein the protection film is coated on the member by using an ion plating method.

5. The member for the plasma processing apparatus of claim 1, further comprising a ceiling plate, configured to radiate microwaves into the processing container, installed within the processing container, and the protection film is coated on the ceiling plate.

6. The member for the plasma processing apparatus of claim 1, wherein the protection film is formed of any one of yttria, oxide-based ceramics, metal fluoride, metal acid fluoride and metal carbide.

7. A plasma processing apparatus configured to generate plasma in a processing space of a processing container and to perform plasma processing on an object to be processed, the plasma processing apparatus comprising a member for the plasma processing apparatus, the member having a protection film coated on a face of the member exposed to the plasma,
wherein the protection film includes a columnar structure having a plurality of column-shaped portions in substantially cylindrical shapes extending in a thickness direction of the film, the plurality of column-shaped portions being collected to be adjacent to one another without gaps therebetween.

8. The plasma processing apparatus of claim 7, wherein the protection film has a thickness not less than 10 μm but not greater than 100 μm.

9. The plasma processing apparatus of claim 7, wherein the protection film has a surface roughness not greater than 3 μm.

10. The plasma processing apparatus of claim 7, wherein the protection film is coated on the member by using an ion plating method.

11. The plasma processing apparatus of claim 7, further comprising a ceiling plate, configured to radiate microwaves into the processing container, installed within the processing container, and the protection film is coated on the ceiling plate.

12. The plasma processing apparatus of claim 7, wherein the protection film is formed of any one of yttria, oxide-based ceramics, metal fluoride, metal acid fluoride and metal carbide.
